(19) United States
(12) Patent Application Publication
(10) Pub. No.: US 2018/0076168 A1
(43) Pub. Date: Mar. 15, 2018

(54) Fluidic Self Assembly of Contact Materials

(71) Applicant: SHARP LABORATORIES OF AMERICA, INC., CAMAS, WA (US)

(72) Inventors: LISA H. STECKER, VANCOUVER, WA (US); KENJI ALEXANDER SASAKI, WEST LINN, OR (US); DAVID ROBERT HEINE, HORSEHEADS, NY (US)

(21) Appl. No.: 15/264,486

(22) Filed: Sep. 13, 2016

(51) Int. Cl. H01L 23/00; H01L 33/62

(52) U.S. Cl. CPC H01L 24/75; H01L 33/62; H01L 2924/01322; H01L 2924/01079; H01L 2933/0066; H01L 2924/0105; H01L 2924/12041; H01L 2224/75655; H01L 2224/75343; H01L 2924/01032

(57) ABSTRACT

Embodiments are related to systems and methods for fluidic assembly, and more particularly to systems and methods for forming contacts during fluidic assembly.

### FIELD OF THE INVENTION

Embodiments are related to systems and methods for fluidic assembly, and more particularly to systems and methods for forming contacts during fluidic assembly.

### BACKGROUND

LED displays, LED display components, and arrayed LED devices include a large number of diodes formed or placed at defined locations across the surface of the display or device. Fluidic assembly may be used for assembling diodes in relation to a substrate for use in manufacturing LED devices. Such assembly can result in excessive resistance between the diodes and electrical contacts formed on the substrate. Using a metallic contact integrally connecting the diodes with the electrical contacts formed on the substrate would reduce resistances. However, such integral connectivity using a metallic contact is not easily formed using conventional technologies resulting in high costs and low reliability.

Hence, for at least the aforementioned reasons, there exists a need in the art for advanced systems and methods for manufacturing LED displays, LED display components, and LED devices.

### BRIEF DESCRIPTION OF THE FIGURES

A further understanding of the various embodiments of the present invention may be realized by reference to the figures which are described in remaining portions of the specification. In the figures, like reference numerals are used throughout several figures to refer to similar components. In some instances, a sub-label consisting of a lower case letter is associated with a reference numeral to denote one of multiple similar components. When reference is made to a reference numeral without specification to an existing sub-label, it is intended to refer to all such multiple similar components.

FIG. 1a-1b show a portion of a substrate including a well into which a diode object is deposited and soldered in accordance with various embodiments of the present inventions;

FIGS. 2a-2b show a portion of another substrate including a well and a through-hole via, where a diode object is deposited and soldered into the well in accordance with some embodiments of the present inventions;

FIG. 3 depicts a fluidic assembly system capable of moving a suspension composed of a carrier liquid and a large number of solder particles relative to the surface of a substrate in accordance with one or more embodiments of the present inventions;

FIGS. 4a-4e show a portion of a substrate including a well into which solder particles are deposited followed by deposition of a diode object in accordance with various embodiments of the present inventions;

FIG. 5 depicts a fluidic assembly system capable of moving a suspension composed of a carrier liquid and a plurality of diode objects relative to the surface of a substrate including wells into which solder particles were previously deposited in accordance with one or more embodiments of the present inventions;

FIG. 6 shows a portion of a substrate including a well with a through-hole via extending from the well to a bottom surface of the substrate, where solder particles may be deposited in accordance with some embodiments of the present inventions; and

FIG. 7 is a flow diagram depicting a method in accordance with one or more embodiments of the present inventions for forming solder particles within wells of a substrate.

### DETAILED DESCRIPTION OF SOME EMBODIMENTS

Embodiments are related to systems and methods for fluidic assembly, and more particularly to systems and methods for forming contacts during fluidic assembly.

Various embodiments provide electronic assembly systems that include a suspension having a carrier liquid and a plurality of solder particles. In some instances of the aforementioned embodiments, the solder particles are formed of eutectic solder material and/or non-eutectic solder material. In some cases, the solder particles are formed from an Au/Ge solder material. In other cases, the solder particles are formed from an Au/Sn solder material. In one or more instances of the aforementioned embodiments, the systems further include a substrate. The substrate has a well including one or more of the solder particles settled out from the suspension near a corner of the well. In some such cases, an object is deposited in the well on top of the one or more of the solder particles settled out from the suspension near the corner of the well. In particular cases, the object is a diode. In some instances of the aforementioned embodiments, the solder particles are formed in part by directing ultrasonic waves at a solder material.

In various instances of the aforementioned embodiments, the system further includes: a substrate and a suspension moving device. The substrate includes a well, and the suspension is deposited on the well. The suspension movement device is operable to move the suspension over the substrate such that a first flow rate near a corner of the well is less than a second flow rate outside the well. The difference between the first flow rate and the second flow rate encourages a first subset of the plurality of the solder particles to settle out in the first flow rate, but a second subset of the plurality of particles to remain in suspension in the second flow rate.

Other embodiments provide methods for device assembly that include: depositing a suspension on a substrate including a non-planar structure where the suspension includes a carrier liquid and a plurality of solder particles; agitating the suspension relative to the substrate such that a first flow rate of the suspension at a first location relative to the non-planar structure is less than a second flow rate of the suspension at a second location relative to the non-planar structure, where a difference between the first flow rate and the second flow rate encourages a first subset of the plurality of the solder particles to settle out near the first location, but a second subset of the plurality of particles to remain in the suspension near the second location. The solder particles may be formed of either a eutectic solder material or a non-eutectic solder material.

In some instances of the aforementioned embodiments, the non-planar structure may be, but is not limited to, a trench or a well. In various instances of the aforementioned embodiments, the non-planar structure is a well, the first location is in a corner of the well, and the second location is near a center of the well. In one or more instances of the aforementioned embodiments, the methods further include: forming the plurality of solder particles; and adding the plurality of solder particles to the carrier liquid to make the suspension. In some instances of the aforementioned embodiments, the methods further include draining the suspension from the substrate, where the first subset of the plurality of the solder particles remain on the substrate. In some cases, the methods additionally include sintering the first subset of the solder particles. In some cases, the methods further include: depositing an object in the non-planar structure on the first subset of the solder particles, and annealing the substrate such that the first subset of the solder particles connect the object to the substrate.

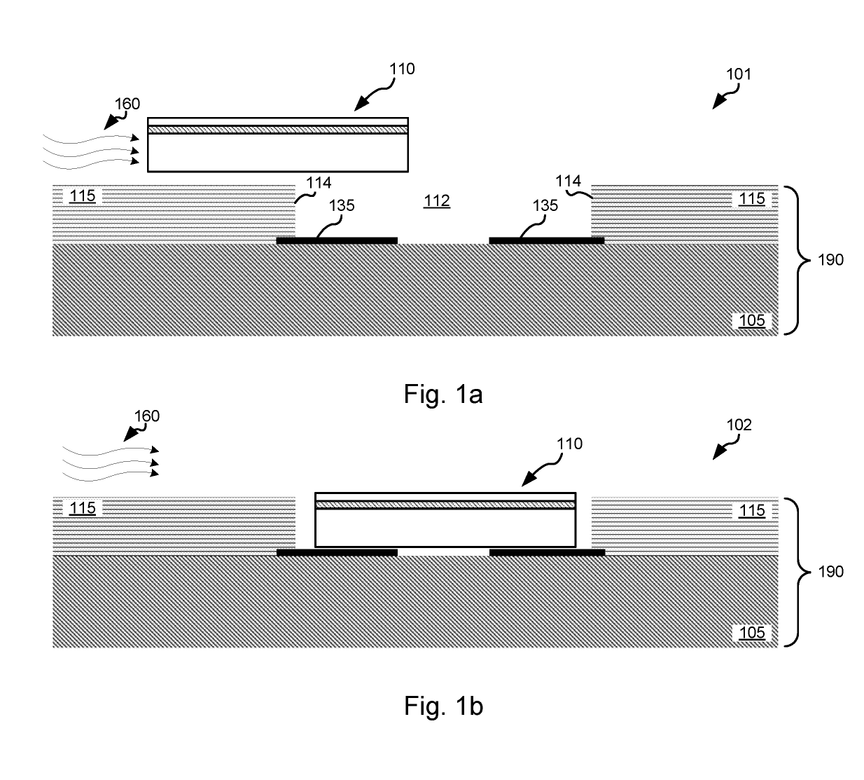

Turning to FIG. 1a, a cross sectional view 101 of a portion of a substrate 190 including a well 112 into which a diode object 110 can be deposited and soldered is shown in accordance with some embodiments of the present inventions. As used herein, the term “well” is used in its broadest sense to mean any surface feature into which solder particles may deposit and collect near the bottom corners of the well. As shown, substrate 190 is composed of a polymer material 115 laminated to the surface of a glass layer 105. It should be noted that materials other than glass may be used in place of glass layer 105. Additionally, other conductive or non-conductive layers may exist between material 115 and layer 105. In some embodiments, a conductive material is deposited over layer 105 and patterned to form electrical contacts. Further, it should be noted that in some cases polymer material 115 may be replaced by glass or another suitable material. In some embodiments, substrate 115 is made by forming an electric contact layer on the surface of glass layer 105, and etching the electric contact layer to yield an electrical contact 135 at a location corresponding to a future well. It should be noted that while electrical contact 135 is shown as covering only a portion of the base of well 112, that it may cover the entire base of well 112 as there is not a through-hole via. Polymer material 115 is then laminated over glass layer 105 and electrical contact 135, followed by an etch of polymer material 115 to open well 112 defined by a sidewall 114 and expose a portion of electrical contact 135. Electrical contact 135 may be formed of any material capable of forming an electrical junction with bottom surface 275 of a diode object 110. In some cases, electrical contact 135 is formed of a metal that when annealed with a diode object 110 disposed within well 112 forms an electrically conductive location between a signal connected to electrical contact 135 and electrically conductive material 270 of a diode object 110. In some embodiments, the depth of well 112 is substantially equal to the height (Hd) of diode object 110 such that only one diode object 110 deposits in well 112. It should be noted that while specifics of the substrate, wells and diode objects are discussed herein, that the processes discussed herein may be used in relation to different substrates, wells and other objects.

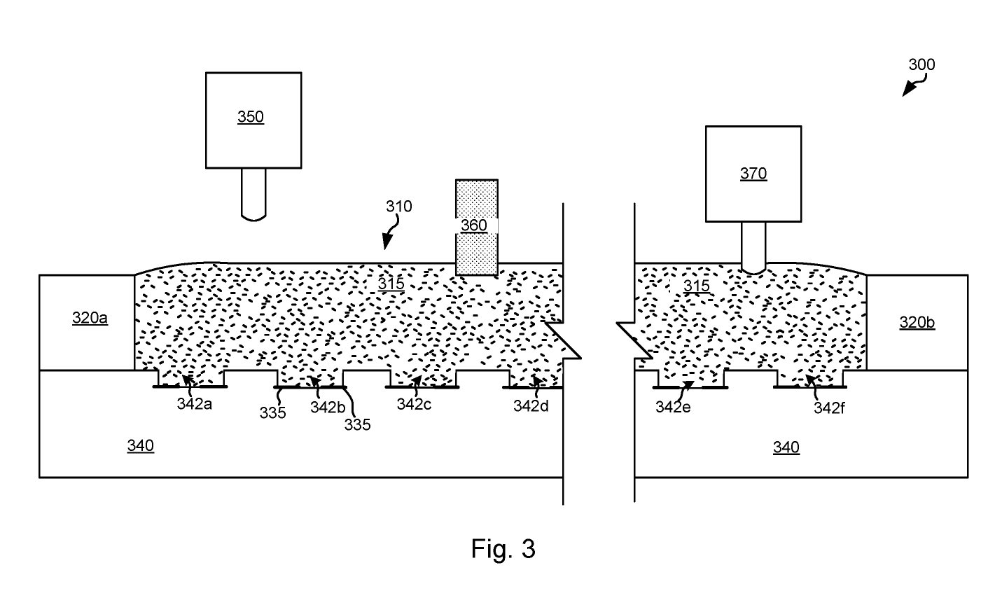

During fluidic assembly a liquid flow (indicated by arrows 160) results in drag forces on diode objects 110 traversing the surface of substrate 190. As shown in a cross-sectional view 102 of FIG. 1b, the liquid flow pushes diode object 110 along the surface of substrate 190 until it deposits into well 112. In this deposited position, diode object 110 rests in casual contact with electrode 135. In some cases, this casual contact results in excessively high resistance with all of the attending issues associated therewith including, but not limited to, excess heat production. Advanced fluidic assembly processes, methods, apparatus, and systems capable of creating a less resistive contact between electrode 135 and diode object 110 are discussed below in relation to FIGS. 3-5 and 7.

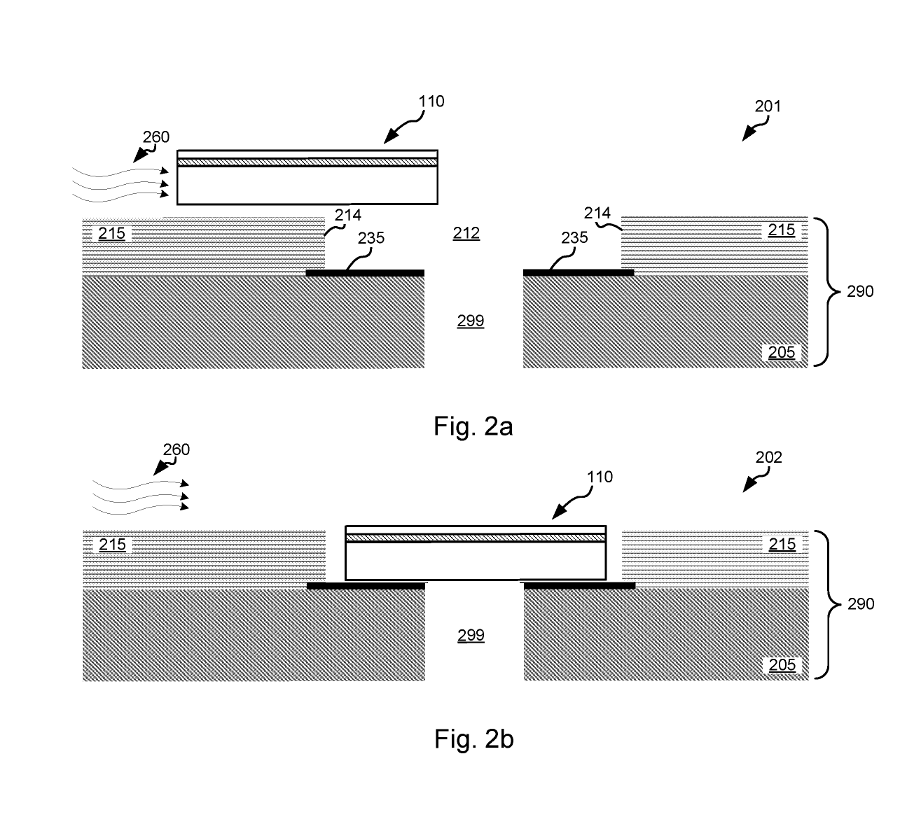

Turning to FIG. 2a, a cross sectional view 201 of a portion of a substrate 290 including a well 212 into which a diode object 110 can be deposited and soldered is shown in accordance with some embodiments of the present inventions. In contrast to that discussed above in relation to FIG. 1a-1b, a through-hole via 299 extends from the bottom of well 212 through to the bottom of substrate 290. It should be noted that advanced fluidic assembly processes, methods, apparatus, and systems capable of creating a less resistive contacts generally discussed below in relation to FIGS. 3-8 may be applied to substrates including wells with or without through-hole vias.

As shown, substrate 290 is composed of a polymer material 215 laminated to the surface of a glass layer 205. It should be noted that materials other than glass may be used in place of glass layer 205. Additionally, other conductive or non-conductive layers may exist between material 215 and layer 205. Further, it should be noted that in some cases polymer material 215 may be replaced by glass or another suitable material. In some embodiments, substrate 215 is made by forming an electric contact layer on the surface of glass layer 205, and etching the electric contact layer to yield an electrical contact 235 at a location corresponding to a future well. It should be noted that while electrical contact 235 is shown as covering only a portion of the base of well 212, that it may cover the entire base of well 212 as there is not a through-hole via. Polymer material 215 is then laminated over glass layer 205 and electrical contact 235, followed by an etch of polymer material 215 to open well 212 defined by a sidewall 214 and expose a portion of electrical contact 235. Electrical contact 235 may be formed of any material capable of forming an electrical junction with bottom surface 275 of a diode object 110. In some cases, electrical contact 235 is formed of a metal that when annealed with a diode object 110 disposed within well 212 forms an electrically conductive location between a signal connected to electrical contact 235 and electrically conductive material 270 of a diode object 110. In some embodiments, the depth of well 212 is substantially equal to the height (Hd) of diode object 110 such that only one diode object 110 deposits in well 212. It should be noted that while specifics of the substrate, wells and diode objects are discussed herein, that the processes discussed herein may be used in relation to different substrates, wells and other objects.

During fluidic assembly a liquid flow (indicated by arrows 260) results in drag forces on diode objects 110 traversing the surface of substrate 290. As shown in a cross-sectional view 202 of FIG. 2b, the liquid flow pushes diode object 110 along the surface of substrate 290 until it deposits into well 212. In this deposited position, diode object 110 rests in casual contact with electrode 235. In some cases, this casual contact results in excessively high resistance with all of the attending issues associated therewith including, but not limited to, heat production. Similar to that discussed above in relation to FIG. 1a-1b, advanced fluidic assembly processes, methods, apparatus, and systems capable of creating a less resistive contact between electrode 135 and diode object 110 are discussed below in relation to FIGS. 3 and 5-7.

Turning to FIG. 3, a fluidic assembly system 300 capable of moving a suspension 310 composed of a carrier liquid 315 and a large number of solder particles (shown as small black elements within carrier liquid 315) relative to the surface of a substrate 340 is shown in accordance with one or more embodiments of the present inventions. In some embodiments, substrate 340 is formed of a polymer material laminated to the surface of a glass substrate. In particular embodiments, wells 342 are etched or otherwise formed in the laminate layer. In other embodiments, the substrate is made of glass with wells 342 directly formed into the glass. Wells 342 may have flat and vertical surfaces as shown, or they may have bottoms and sides with complex curvatures. Wells may be of any size or shape, but in some embodiments exhibit a circular opening with a diameter between twenty (20) μm and one hundred, fifty (150) μm. Based upon the disclosure provided herein, one of ordinary skill in the art will recognize a variety of materials, processes, and/or structures that may be used to form substrate 340. For example, substrate 340 can be formed of any material or composition compatible with fluidic device processing. This can include, but is not limited to, glass, glass ceramic, ceramic, polymer, metal, or other organic or inorganic materials. As examples, wells 342 can be defined in a single material forming a surface feature layer when applied to the surface of a base glass sheet. It is also possible for patterned conductor layers to exist between wells 342 formed in such a surface feature layer and the base glass layer. Substrate 340 can also be made of multiple layers or combinations of these materials. Substrate 340 may be a flat, curved, rigid, or flexible structure. In some cases, substrate 340 may end up being the final device substrate or it may only serve as an assembly substrate to position solder particles. In the case of an assembly substrate, solder particles would then be transferred to the final device substrate in subsequent steps.

In some embodiments, carrier liquid 315 is isopropanol. Based upon the disclosure provided herein, one of ordinary skill in the art will recognize a variety of liquids, gasses, and/or liquid and gas combinations that may be used as the carrier liquid. It should be noted that various analysis provided herein is based upon flow in a single, continuous direction or in other cases a relatively simple back-forth motion, but that the flow may be more complex where both the direction and magnitude of fluid velocity can vary over time.

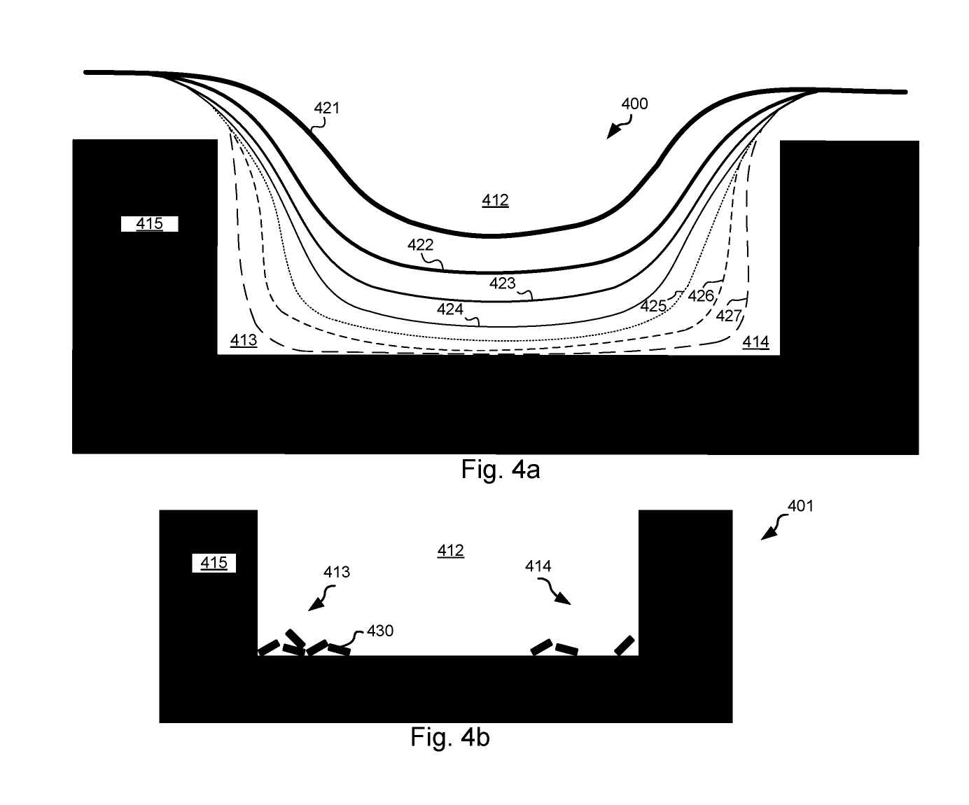

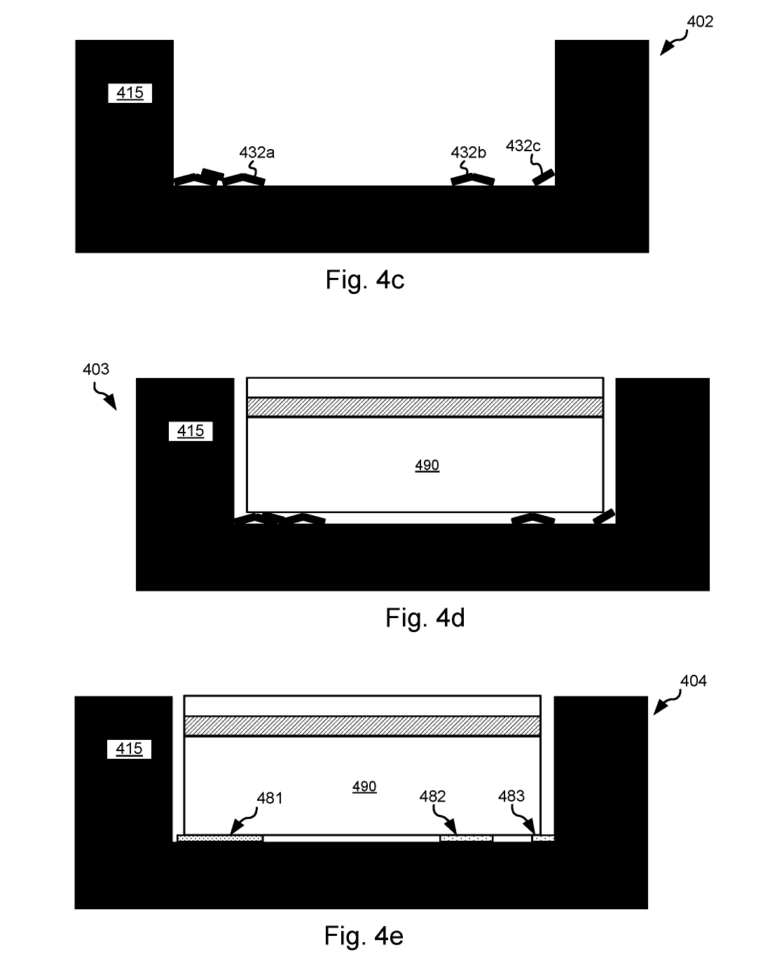

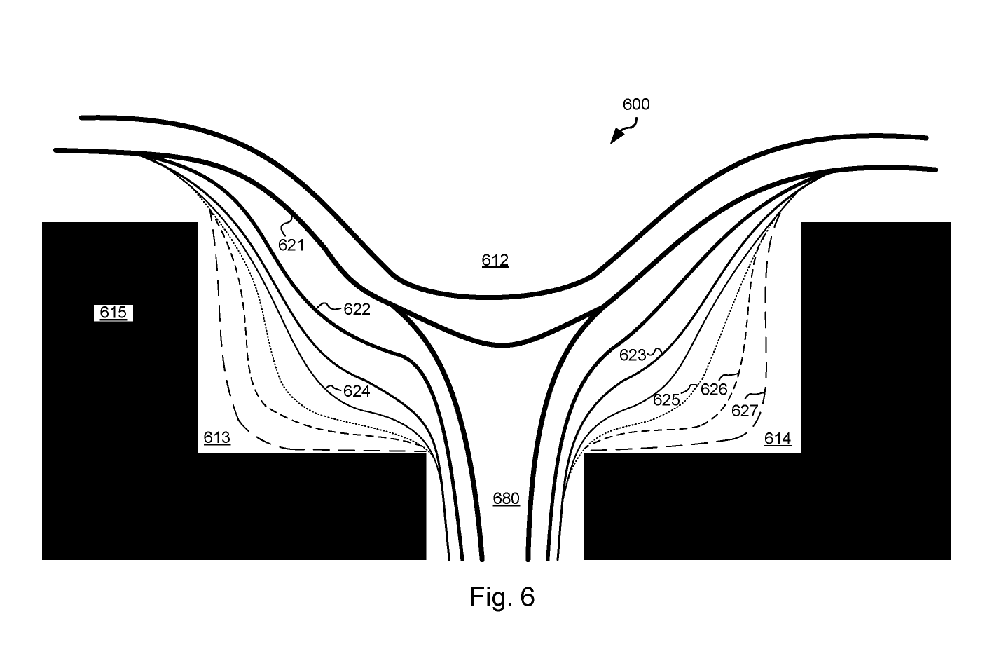

The solder particles may be made of any material capable of reducing resistance between electrodes 335 along the bottom of wells 342 and a diode object (not shown) deposited in a given one of wells 342. In some embodiments, the solder particles are eutectic solder particles that are not neutrally buoyant and will tend to settle out of carrier liquid 315 in lower velocity regions and remain suspended in the carrier liquid 315 in higher velocity regions. Examples of such lower velocity regions and higher velocity regions are discussed in detail below in relation to FIGS. 4a and 6. The propensity of a solder particle to settle out or remain suspended is a function of the varying flow rates (i.e., the flow profile) of carrier liquid 315, and the characteristics of the solder particles including the density of a given solder particle and the hydrodynamic radius of the given solder particle in carrier liquid 315. The density of a solder particle is selected by choosing the material from which to make the solder particle. The hydrodynamic radius of a solder particle may be engineered by changing the aspect ratio of the solder particle. It should be noted that the solder particles may be made of a number of different materials including both eutectic materials and non-eutectic materials. As just some examples, the solder particles may be made of Au/Ge or Au/Sn. Based upon the disclosure provided herein, one of ordinary skill in the art will recognize a variety of materials that may be used to form the solder particles.

In some embodiments, solder particles are formed by depositing a solder particle material on top of a base structure. In some embodiments, the solder particle material is a mixture of Gold and Germanium formed as an Au/Ge metallized layer on the top of the base structure. This deposition of the solder particle material includes evaporating solder material layers with poor adhesion, and cycling through proportional layering. The base structure may be, but is not limited to, a photoresist layer formed on top of a silicon layer. Once the solder particle material is deposited on top of the base structure, layer peeling may be enhanced by mechanical grinding or other manipulation. Then, the overall structure is exposed to ultrasonic waves and additional mechanical milling to reduces the solder particle size. Larger solder particles are filtered out, and the remaining smaller solder particles are introduced into carrier fluid 315 to yield suspension 310.

As shown in FIG. 3, the solder particles move relative to a surface of substrate 340 at times falling into wells 342. The flow profile of suspension 310 relative to the surface of substrate 340 exhibits a flow rate near the lower corners of wells 342 that is substantially lower than the flow rate of suspension 310 away from the lower corner of wells 342. This differential in flow rates results in solder particles settling out onto electrodes 335 near the lower corners of wells 342, while solder particles in other regions of suspension 310 remain buoyant. Once established in the lower corners of wells 342, gravity and Van der Waals stiction holds the deposited solder particles in place while the remaining suspension 310 is removed. Removal of the remaining suspension 310 is done differently depending upon whether or not a through-hole via extends from the bottom of each of wells 342 to a bottom surface of substrate 340. Where a through-hole via extends from the bottom of each well 342, suspension 310 is merely allowed to drain under gravitation force through the through-hole vias into a collection area (not shown) where it is recovered for later use. While suspension 310 is draining it is replaced with neat liquid (e.g., carrier liquid 315 without solder particles) to assure removal of solder particles that may have settled out when the flow of the draining suspension reduced. Alternatively, where wells 342 are closed bottomed (i.e., no through-hole via), suspension 310 is drained from the top surface of substrate 340 while additional neat liquid (e.g., carrier liquid 315 without solder particles) is added in place of the draining suspension 310 to assure removal of solder particles that may have settled out when the flow of the draining suspension reduced. In either cases, the removed suspension 310 may be collected and reused.

The remaining neat liquid is allowed to evaporate leaving the solder particles deposited near the corners of wells 342. In some cases, to improve the mechanical stability of the remaining solder particles, the deposited solder particles are sintered together by heating substrate 340.

Turning to FIGS. 4a-4d, a portion of a substrate 415 including a well 412 into which solder particles 430 are deposited followed by deposition of a diode object 490 is shown in accordance with various embodiments of the present inventions. As shown in FIG. 4a, a cross-section 400 shows flow rates of a suspension passing over well 412 at different areas within the well. The flow rates are shown as lines with differing thickness and fill. In particular, a highest flow rate 421 is shown as a relatively thick, solid line and a lowest flow rate 427 is shown with a relatively thin, relatively wide dashed line. The flow rate progressively decreases from highest flow rate 421 to lowest flow rate 427. In particular, a next highest flow rate 422 is shown as a solid line that is slightly thinner than that of highest flow rate 421; a next highest flow rate 423 is shown as a solid line that is slightly thinner than that of flow rate 422; a next highest flow rate 424 is shown as a solid line that is slightly thinner than that of flow rate 423; a next highest flow rate 425 is shown as a dashed line with close dashes; and a next highest flow rate 426 is shown as a dashed line with farther dashes than that of flow rate 425.

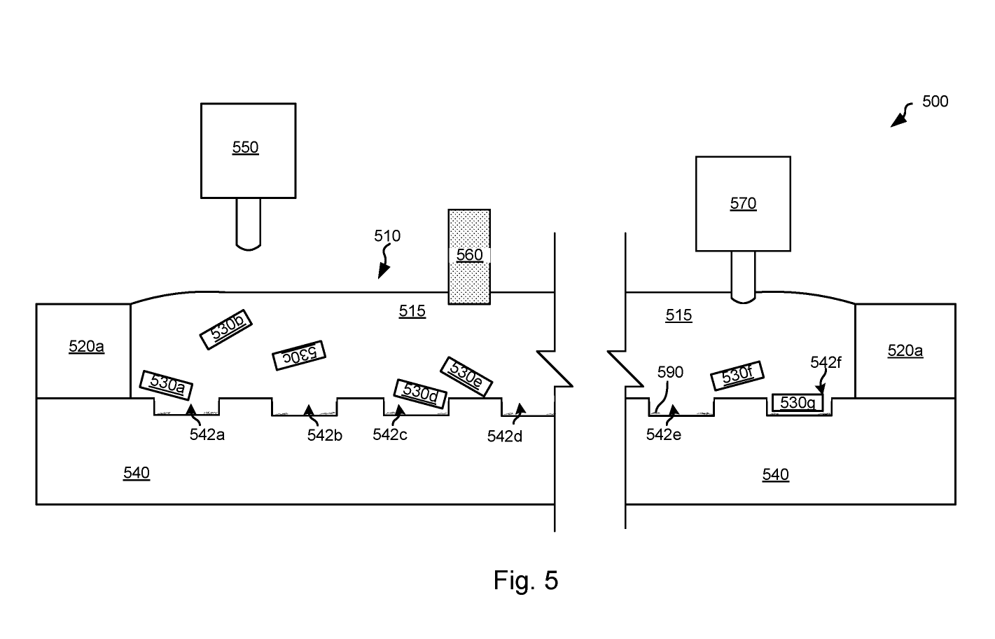

As shown in FIG. 4a, areas 413, 414 of well 412 are exposed to the lowest flow rates, and as such solder particles 430 within the flowing suspension are most likely to settle out of the suspension and deposit in areas 413, 414. A cross section 401 of FIG. 4b shows an example of such solder particles 430 in areas 413, 414 near the corners of well 412. Once enough time has passed to allow a number of solder particles 430 to settle out in areas 413, 414, substrate 415 may be heated to sinter the deposited solder particles 430 to yield sintered particles 432 as shown in cross section 402 of FIG. 4c. Sintering is used in some cases to enhance the mechanical stability of the deposited solder particles. As shown in cross-section 403 of FIG. 4d, diode object 490 is deposited into well 412 on top of sintered particles 432. The process of depositing diode object 490 into well 412 is discussed in greater detail below in relation to FIG. 5. Next, as shown in cross section 404 of FIG. 4e, substrate 415 is exposed to an annealing process where sintered particles 432 are heated such that the solder melts leaving soldered contacts 481, 482, 483 between an electrode on a bottom surface of diode object 490 and a bottom surface of well 412.

Turning to FIG. 5, a fluidic assembly system 500 is shown that is capable of moving a suspension 510 composed of a carrier liquid 515 and a plurality of diode objects 530 relative to the surface of a substrate 540 including wells 542 into which solder particles 590 were previously deposited in accordance with one or more embodiments of the present inventions. In some cases, the depth of wells 542 is substantially equal to the height of diode objects 530, and the inlet opening of wells 542 is greater that the width of diode objects 530 such that only one diode object 530 deposits into any given well 542. It should be noted that while embodiments discuss depositing diode objects 530 into wells 542, that other devices or objects may be deposited in accordance with different embodiments of the present inventions.

A depositing device 550 deposits suspension 510 over the surface of substrate 540 with suspension 510 held on top of substrate 540 by sides 520 of a dam structure. In some embodiments, depositing device 550 is a pump with access to a reservoir of suspension 510. A suspension movement device 560 agitates suspension 510 deposited on substrate 540 such that diode objects 530 move relative to the surface of substrate 540. As diode objects 530 move relative to the surface of substrate 540 they deposit into wells 542 in either a non-inverted orientation or an inverted orientation. In some embodiments, suspension movement device 560 is a brush that moves in three dimensions. Based upon the disclosure provided herein, one of ordinary skill in the art will recognize a variety of devices that may be used to perform the function of suspension movement device 560 including, but not limited to, a pump.

A capture device 570 includes an inlet extending into suspension 510 and capable of recovering a portion of suspension 510 including a portion of carrier liquid 515 and non-deposited diode objects 530, and returning the recovered material for reuse. In some embodiments, capture device 570 is a pump.

It should be noted that while FIGS. 4-5 were described with wells that do not include through-hole vias extending from the bottom of the wells to the bottom of the substrate, a similar process for forming solder particles in the wells may be used where the wells include a through-hole via. Turning to FIG. 6, a cross section 600 shows a portion of a substrate 615 including a well 612 and a through-hole via 680, and shows flow rates of a suspension passing over well 612 at different areas within the well and through the through hole via. In particular, a highest flow rate 621 is shown as a relatively thick, solid line and a lowest flow rate 627 is shown with a relatively thin, relatively wide dashed line. The flow rate progressively decreases from highest flow rate 621 to lowest flow rate 627. In particular, a next highest flow rate 622 is shown as a solid line that is slightly thinner than that of highest flow rate 621; a next highest flow rate 623 is shown as a solid line that is slightly thinner than that of flow rate 622; a next highest flow rate 624 is shown as a solid line that is slightly thinner than that of flow rate 623; a next highest flow rate 625 is shown as a dashed line with close dashes; and a next highest flow rate 626 is shown as a dashed line with farther dashes than that of flow rate 625. As shown, areas 613, 614 of well 612 are exposed to the lowest flow rates, and as such solder particles (not shown) within the flowing suspension are most likely to settle out of the suspension and deposit in areas 613, 614. Once the solder particles settle in areas 413, 414, the processes applied to wells with through-hole vias is substantially the same.

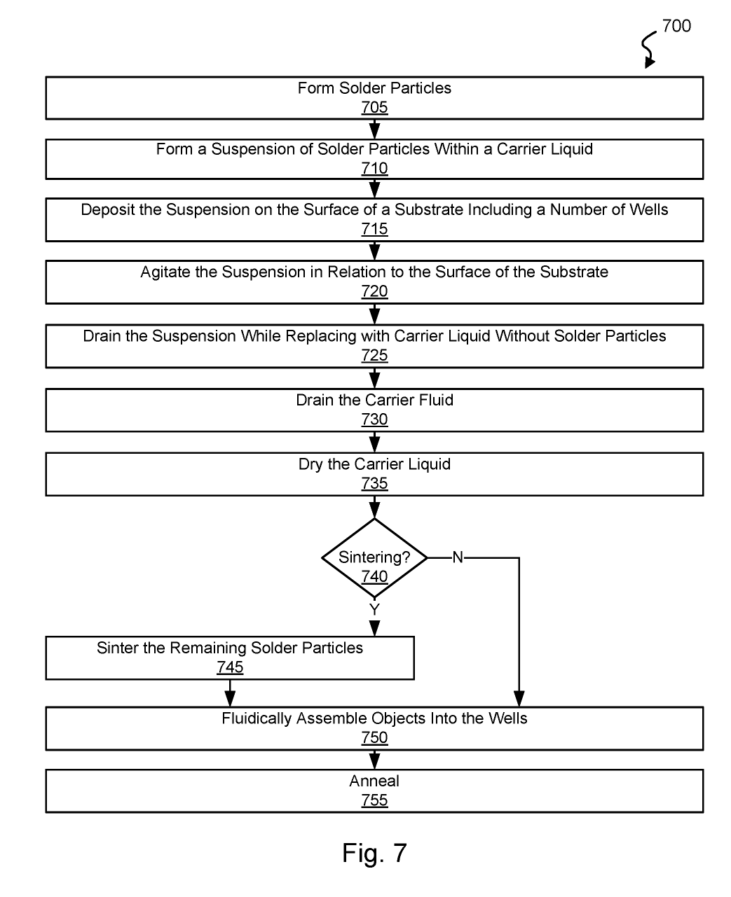

Turning to FIG. 7, a flow diagram 700 shows a method in accordance with one or more embodiments of the present inventions for forming solder particles within wells of a substrate. Following flow diagram 700, solder particles are formed (block 705). The propensity of a solder particle to settle out or remain suspended is a function of the varying flow rates (i.e., the flow profile) of a carrier liquid, and the characteristics of the solder particles including the density of a given solder particle and the hydrodynamic radius of the given solder particle in the carrier liquid. The density of a solder particle is selected by choosing the material from which to make the solder particle. The hydrodynamic radius of a solder particle may be engineered by changing the aspect ratio of the solder particle. Any process for forming particles of a solder material that exhibit buoyancy in a high flow area, but settle out in a low flow area may be used in relation to embodiments of the present inventions.

Further, the solder particles may be made of a number of different materials including both eutectic materials and non-eutectic materials. As just some examples, the solder particles may be made of Au/Ge or Au/Sn. Based upon the disclosure provided herein, one of ordinary skill in the art will recognize a variety of materials that may be used to form the solder particles.

In some embodiments, solder particles are formed by depositing a solder particle material on top of a base structure. In some embodiments, the solder particle material is a mixture of Gold and Germanium formed as an Au/Ge metallized layer on the top of the base structure. This deposition of the solder particle material includes evaporating solder material layers with poor adhesion, and cycling through proportional layering. The base structure may be, but is not limited to, a photoresist layer formed on top of a silicon layer. Once the solder particle material is deposited on top of the base structure, layer peeling may be enhanced by mechanical grinding or other manipulation. Then, the overall structure is exposed to ultrasonic waves and additional mechanical milling to reduces the solder particle size. Larger solder particles are then filtered out to leave a group of solder particles that may be used in processing.

The group of solder particles are added to a carrier liquid to make a suspension (block 710). Any liquid capable of moving solder particles at high flow rate regions, and allowing the solder particles to settle out in lower flow rate regions may be used in accordance with different embodiments of the present inventions. In some embodiments, the carrier liquid is isopropanol. Based upon the disclosure provided herein, one of ordinary skill in the art will recognize a variety of liquids, gasses, and/or liquid and gas combinations that may be used as the carrier liquid.

The suspension is deposited on the surface of a substrate including a number of wells (block 715). In some embodiments the wells include through-hole vias extending from the bottom of the wells to the bottom of the substrate. In other embodiments, the wells do not exhibit through-hole vias. The suspension is agitated in relation to the surface of the substrate such that areas of higher flow rates and areas of lower flow rates are created (block 720). Examples of areas with differential flow rates are shown in FIGS. 4a and 6 where the lower flow rates occur in the corners of the wells on the substrate. The agitation may be a single direction flow, a back and forth flow, or some other type of flow. By creating the differential flow rates, the solder particles in the suspension tend to settle out near the corners of the wells.

The suspension is then drained from the surface of the substrate (block 725). In embodiments where the wells do not include through-hole vias, the draining may include pumping the remaining suspension from the surface of the substrate or titling the substrate to drain the excess material. In embodiments where the wells do include through-hole vias, the excess suspension may simply be allowed to drain through the through-hole vias. In either case, as the excess suspension is drained, it is replaced by neat liquid (i.e., the carrier liquid without solder particles) such that solder particles do not settle out during the draining process. Once the draining process is complete, the remaining neat liquid is allowed to dry (block 735).

It is then determined whether a sintering process is to be completed (block 740). Where sintering is to be completed (block 740), the deposited solder particles are sintered together by heating the substrate (block 745). Such sintering enhances the mechanical stability of the remaining solder particles. Objects are then fluidically assembled into the wells on top of the solder particles (block 750). Once the fluidic assembly of the objects is complete (block 750), the substrate is annealed such that the solder particles integrally connect the object to the substrate within the wells (block 755).

One of ordinary skill in the art will recognize various advantages achievable through use of different embodiments of the inventions. As just some of many advantages, lower display costs are possible as a significant cost of manufacturing a microLED display is the material cost of the microLEDs themselves. As some embodiments of the present inventions allow for reducing redundancy otherwise necessary to assure an operable display, the overall number of microLEDs may be reduced resulting in a corresponding reduction in costs. Various embodiments of the present inventions do not require lock-n-key type interaction between post enhanced diodes and wells which allow diodes to deposit in only a single orientation. As such, manufacturing tolerances may be reduced leading to greater yields and/or lower costs. Based upon the disclosure provided herein, one of ordinary skill in the art will recognize a variety of other advantages achievable through use of one or more embodiments of the present inventions.

Additionally, while the inventions have been discussed in relation to assembling diode objects into cylindrical wells, it should be noted that the inventions discussed herein may be used, for example, to deposit solder particles into a trench formed on a substrate surface. All such surface features in the substrate including, but not limited to, wells and trenches are referred to herein as “non-planar structures”. As used herein, a “non-planar structure” is any feature on or in the substrate which causes differential flow rates in a suspension being agitated relative to the surface of the substrate. By flowing a suspension including solder particles perpendicular to the trench, some of the solder particles will settle out in the trench. The substrate may then be heated resulting in the formation of a metal wire on the surface of the substrate as defined by the trench. Further, some embodiments may use a carrier liquid that includes a fluxing material that remains after the neat liquid is evaporated or dried.

In conclusion, the invention provides novel systems, devices, methods and arrangements for fluidic assembly. While detailed descriptions of one or more embodiments of the invention have been given above, various alternatives, modifications, and equivalents will be apparent to those skilled in the art without varying from the spirit of the invention. For examples, while some embodiments are discussed in relation to displays, it is noted that the embodiments find applicability to devices other than displays. Therefore, the above description should not be taken as limiting the scope of the invention, which is defined by the appended claims.

What is claimed is:

1. An electronics assembly system, the system comprising:
a suspension including a carrier liquid and a plurality of solder particles.

2. The system of claim 1, wherein the solder particles are formed of eutectic solder material.

3. The system of claim 1, wherein the solder particles are formed of non-eutectic solder material.

4. The system of claim 1, wherein the solder particles are formed from a solder material selected from a group consisting of: Au/Ge, and Au/Sn.

5. The system of claim 1, wherein the system further comprises:
a substrate including a well, wherein the well includes one or more of the solder particles settled out from the suspension near a corner of the well.

6. The system of claim 5, wherein the system further comprises:
an object deposited in the well on top of the one or more of the solder particles settled out from the suspension near the corner of the well.

7. The system of claim 6, wherein the object is a diode.

8. The system of claim 1, wherein the system further comprises:
a substrate including a well, wherein the suspension is deposited on the substrate;
a suspension movement device operable to move the suspension over the substrate such that a first flow rate near a corner of the well is less than a second flow rate outside the well, wherein the difference between the first flow rate and the second flow rate encourages a first subset of the plurality of the solder particles to settle out in the first flow rate, but a second subset of the plurality of particles to remain in suspension in the second flow rate.

9. The method of claim 1, wherein the solder particles are formed in part by directing ultrasonic waves at a solder material.

10. A method for device assembly, the method comprising:
depositing a suspension on a substrate including a non-planar structure, wherein the suspension includes a carrier liquid and a plurality of solder particles;
agitating the suspension relative to the substrate such that a first flow rate of the suspension at a first location relative to the non-planar structure is less than a second flow rate of the suspension at a second location relative to the non-planar structure, wherein a difference between the first flow rate and the second flow rate encourages a first subset of the plurality of the solder particles to settle out near the first location, but a second subset of the plurality of particles to remain in the suspension near the second location.

11. The method of claim 10, wherein the non-planar structure is selected from a group consisting of: a trench, and a well.

12. The method of claim 10, wherein the non-planar structure is a well, wherein the first location is in a corner of the well, and wherein the second location is near a center of the well.

13. The method of claim 10, wherein the solder particles are formed of eutectic solder material.

14. The method of claim 10, wherein the solder particles are formed of non-eutectic solder material.

15. The method of claim 10, wherein the solder particles are formed from a solder material selected from a group consisting of: Au/Ge, and Au/Sn.

16. The method of claim 10, the method further comprising:
forming the plurality of solder particles; and
adding the plurality of solder particles to the carrier liquid to make the suspension.

17. The method of claim 10, the method further comprising:
draining the suspension from the substrate, wherein the first subset of the plurality of the solder particles remain on the substrate.

18. The method of claim 17, the method further comprising:
sintering the first subset of the solder particles.

19. The method of claim 17, the method further comprising:
depositing an object in the non-planar structure on the first subset of the solder particles.

20. The method of claim 19, wherein the object is a diode.

21. The method of claim 19, annealing the substrate such that the first subset of the solder particles connect the object to the substrate.

22. An electronics assembly system, the system comprising:
a suspension including a carrier liquid and a plurality of solder particles;
a substrate including a non-planar structure;
a suspension movement device operable to move the suspension over the substrate such that a first flow rate of the suspension at a first location relative to the non-planar structure is less than a second flow rate of the suspension at a second location relative to the non-planar structure, wherein a difference between the first flow rate and the second flow rate encourages a first subset of the plurality of the solder particles to settle out near the first location, but a second subset of the plurality of particles to remain in the suspension near the second location.

23. The system of claim 22, wherein the solder particles are formed of eutectic solder material.

24. The system of claim 22, wherein the solder particles are formed of non-eutectic solder material.

25. The system of claim 22, wherein the solder particles are formed from a solder material selected from a group consisting of: Au/Ge, and Au/Sn.

26. The system of claim 22, wherein the non-planar structure is selected from a group consisting of: a trench, and a well.

27. The system of claim 22, wherein the non-planar structure is a well, wherein the first location is in a corner of the well, and wherein the second location is near a center of the well.
